(19) United States
(12) Patent Application Publication
(10) Pub. No.: US 2022/0307779 A1
(43) Pub. Date: Sep. 29, 2022

(54) HEAT DISSIPATION SUBSTRATE FOR INCREASING SOLDERABILITY

(71) Applicants: AMULAIRE THERMAL TECHNOLOGY, INC., New Taipei City (TW); UVAT TECHNOLOGY CO., LTD., Taoyuan City (TW)

(72) Inventors: Min-Horng LIU, New Taipei City (TW); Tze-Yang YEH, New Taipei City (TW); Kuo-Wei LEE, New Taipei City (TW)

(21) Appl. No.: 17/214,909

(22) Filed: Mar. 28, 2021

(51) Int. Cl. F28F 21/08; F28F 13/18

(52) U.S. Cl. CPC F28F 21/084; F28F 21/085; F28F 21/087; F28F 13/18; F28F 2013/001

(57) ABSTRACT

A heat dissipation substrate for increasing solderability is provided. The heat dissipation substrate for increasing solderability includes a heat dissipation layer serving as a base layer, a plating layer formed on the heat dissipation layer, and a protective layer formed on the plating layer. The protective layer is made of one of tin and tin alloy, and the protective layer is capable of being melted in a subsequent process, such that the protective layer is a meltable protective layer.

### FIELD OF THE DISCLOSURE

The present disclosure relates to a heat dissipation substrate, and more particularly to a heat dissipation substrate for increasing solderability.

### BACKGROUND OF THE DISCLOSURE

Most conventional heat dissipation substrates are made of aluminum alloy. However, oxidation resistance of the aluminum alloy weakens under high temperature, and corrosion can easily occur and affect solderability of the aluminum alloy. Therefore, in order to improve the oxidation resistance under high temperature and the solderability of the aluminum alloy, an anti-oxidation treatment is conventionally performed on the aluminum alloy to form alumina on a surface of the aluminum alloy, so that the surface of the aluminum alloy has an anti-oxidation effect. However, the alumina formed on the surface of the aluminum alloy is usually not uniform, and the oxidation resistance and surface hardness of the aluminum alloy are usually not good. With rapid development of the modern industry, the conventional heat dissipation substrates no longer meet higher standards for corrosion resistance and solderability.

Therefore, it has become an important issue in the industry to provide a heat dissipation substrate that meets the higher standards.

### SUMMARY OF THE DISCLOSURE

In response to the above-referenced technical inadequacies, the present disclosure provides a heat dissipation substrate for increasing solderability.

In one aspect, the present disclosure provides a heat dissipation substrate for increasing solderability. The heat dissipation substrate includes a heat dissipation layer that serves as a base layer, a plating layer formed on the heat dissipation layer, and a protective layer formed on the plating layer. The protective layer is made of one of tin and tin alloy, and the protective layer is capable of being melted in a subsequent process, such that the protective layer is a meltable protective layer.

In certain embodiments, the heat dissipation layer is made of one of copper alloy and aluminum alloy.

In certain embodiments, the plating layer is at least one of a nickel plating layer, a copper plating layer, a silver plating layer, a nickel alloy plating layer, a copper alloy plating layer, and a silver alloy plating layer.

In certain embodiments, a thickness of the protective layer is defined to be between 100 nm and 5000 nm.

In certain embodiments, the protective layer is bonded to the plating layer on the heat dissipation layer through physical vapor deposition, chemical plating, or electroplating.

In certain embodiments, a melting point of the protective layer is defined to be between 220° C. and 240° C.

In another aspect, the present disclosure provides a heat dissipation substrate for increasing solderability. The heat dissipation substrate includes a heat dissipation layer that serves as a base layer, and a protective layer formed on the heat dissipation layer. The protective layer is made of one of tin and tin alloy, and the protective layer is capable of being melted in a subsequent process, such that the protective layer is a meltable protective layer.

One of the beneficial effects of the heat dissipation substrate for increasing solderability provided by the present disclosure is that, the protective layer can protect the heat dissipation layer and the plating layer on the heat dissipation layer. Further, a bonding strength and the solderability of the heat dissipation layer and the plating layer are enhanced, such that a service life of the heat dissipation substrate is greatly increased.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a heat dissipation substrate according to a first embodiment of the present disclosure; and

FIG. 2 is a schematic side view of the heat dissipation substrate according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

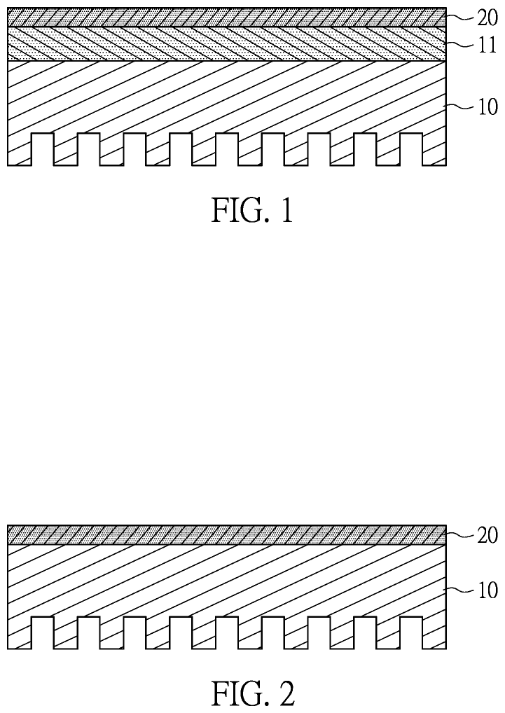

Referring to FIG. 1, FIG. 1 is a schematic side view of a heat dissipation substrate according to a first embodiment of the present disclosure. As shown in the figure, the heat dissipation substrate for increasing solderability includes at least two layers (i.e., a first layer and a second layer) according to the first embodiment of the present disclosure.

The first layer can be a base layer, i.e., a heat dissipation layer 10. The heat dissipation layer 10 can be made of copper alloy, and can also be made of aluminum alloy. In addition, in order to improve a corrosion resistance and a solderability of the heat dissipation layer 10, the heat dissipation layer 10 of this embodiment includes a plating layer structure, i.e., having a plating layer 11 formed on the heat dissipation layer 10. Furthermore, the plating layer 20 may be formed on the heat dissipation layer 10 by plating a single metal thereon. The single metal can be nickel, copper, or silver. Therefore, the plating layer 11 can be a nickel plating layer, a copper plating layer, or a silver plating layer. In other embodiments, the plating layer 11 can be formed on the heat dissipation layer 10 by alloy plating. The alloy metal can be nickel alloy, copper alloy, or silver alloy. Therefore, the plating layer 11 can also be a nickel alloy plating layer, a copper alloy plating layer, or a silver alloy plating layer.

The second layer can be a protective layer 20. The protective layer 20 can be used to protect the plating layer 11 on the heat dissipation layer 10, and can improve the solderability of the heat dissipation layer 10 and the plating layer 11 thereon. Furthermore, the protective layer 20 is made of tin or tin alloy, and the protective layer 20 can be melted in a subsequent process, i.e., the protective layer 20 is a meltable protective layer.

In addition, a thickness of the protective layer 20 in this embodiment is defined to be between 100 nm and 5000 nm to improve the solderability of the plating layer 11. Furthermore, a melting point of the protective layer 20 in this embodiment is defined to be between 220° C. and 240° C. The melting point is relatively low and a melting range is relatively narrow, so as to further improve an overall bonding strength and solderability of the heat dissipation substrate. In addition, the protective layer 20 in this embodiment can be bonded to the plating layer 11 on the heat dissipation layer 10 through physical vapor deposition (PVD), chemical plating, or electroplating.

### Second Embodiment

Referring to FIG. 2, FIG. 2 is a schematic side view of the heat dissipation substrate according to a second embodiment of the present disclosure. As shown in the figure, the heat dissipation substrate for increasing solderability includes at least two layers (i.e., a first layer and a second layer) according to the second embodiment of the present disclosure.

The first layer can be a base layer, i.e., a heat dissipation layer 10. The heat dissipation layer 10 can be made of copper alloy, and can also be made of aluminum alloy.

The second layer can be a protective layer 20. The protective layer 20 can be used to protect the heat dissipation layer 10, and can improve the solderability of the heat dissipation layer 10. Furthermore, the protective layer 20 is made of tin or tin alloy, and the protective layer 20 can be melted in a subsequent process, i.e., the protective layer 20 is a meltable protective layer.

In addition, a thickness of the protective layer 20 in this embodiment is defined to be between 100 nm and 5000 nm to improve the solderability of the heat dissipation layer 10. Furthermore, a melting point of the protective layer 20 in this embodiment is defined to be between 220° C. and 240° C. The melting point is relatively low and a melting range is relatively narrow, so as to further improve the overall bonding strength and solderability of the heat dissipation substrate. In addition, the protective layer 20 in this embodiment can be bonded to the heat dissipation layer 10 through PVD, chemical plating, or electroplating.

### Beneficial Effects of the Embodiments

In conclusion, the protective layer 20 of the heat dissipation substrate for increasing solderability provided by the present disclosure can protect the heat dissipation layer 10 and the plating layer 11 on the heat dissipation layer 10. Further, the bonding strength and the solderability of the heat dissipation layer and the plating layer are enhanced, such that a service life of the heat dissipation substrate is greatly increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat dissipation substrate for increasing solderability, comprising:
a heat dissipation layer serving as a base layer;
a plating layer formed on the heat dissipation layer; and
a protective layer formed on the plating layer;
wherein the protective layer is made of one of tin and tin alloy, and the protective layer is capable of being melted in a subsequent process, such that the protective layer is a meltable protective layer.

2. The heat dissipation substrate according to claim 1, wherein the heat dissipation layer is made of one of copper alloy and aluminum alloy.

3. The heat dissipation substrate according to claim 1, wherein the plating layer is at least one of a nickel plating layer, a copper plating layer, a silver plating layer, a nickel alloy plating layer, a copper alloy plating layer, and a silver alloy plating layer.

4. The heat dissipation substrate according to claim 1, wherein a thickness of the protective layer is defined to be between 100 nm and 5000 nm.

5. The heat dissipation substrate according to claim 1, wherein the protective layer is bonded to the plating layer on the heat dissipation layer through physical vapor deposition, chemical plating, or electroplating.

6. The heat dissipation substrate according to claim 4, wherein a melting point of the protective layer is defined to be between 220° C. and 240° C.

7. A heat dissipation substrate having improved solderability, comprising:
a heat dissipation layer serving as a base layer; and
a protective layer formed on the heat dissipation layer;
wherein the protective layer is made of one of tin and tin alloy, and the protective layer is capable of being melted in a subsequent process, such that the protective layer is a meltable protective layer.

8. The heat dissipation substrate according to claim 7, wherein the heat dissipation layer is made of one of copper alloy and aluminum alloy.

9. The heat dissipation substrate according to claim 7, wherein a thickness of the protective layer is defined to be between 100 nm and 5000 nm.

10. The heat dissipation substrate according to claim 7, wherein the protective layer is bonded to the plating layer on the heat dissipation layer through physical vapor deposition, chemical plating, or electroplating.

11. The heat dissipation substrate according to claim 9, wherein a melting point of the protective layer is defined to be between 220° C. and 240° C.
